(19) United States
(12) Patent Application Publication
(10) Pub. No.: US 2007/0166648 A1
(43) Pub. Date: Jul. 19, 2007

(54) INTEGRATED LITHOGRAPHY AND ETCH FOR DUAL DAMASCENE STRUCTURES

(75) Inventors: Shom Ponoth, Fishkill, NY (US); William G. America, Kingston, NY (US); Timothy A. Brunner, Ridgefield, CT (US); Ronald A. DellaGuardia, Poughkeepsie, NY (US); Kaushal S. Patel, Wappingers Falls, NY (US)

Correspondence Address: INTERNATIONAL BUSINESS MACHINES CORPORATION;DEPT. 18G, BLDG. 300-482, 2070 ROUTE 52, HOPEWELL JUNCTION, NY, 12533, US

(73) Assignee: International Business Machines Corporation, Armonk, NY (US)

(21) Appl. No.: 11/306,935

(22) Filed: Jan. 17, 2006

(51) Int. Cl. G03F 7/26

(52) U.S. Cl. 430/311

(57) ABSTRACT

A method and structure for an integrated via and line lithography followed by integrated via and line etch. A two-layered, negative resist based lithography is used to generate a dual damascene structure in the photoresist which is subsequently transferred into the underlying ILD using an lithography with an integrated RIE. A method is also provided to correct any misalignment between the via and trench during photolithography steps which would reduce the size of the via opening and impact the via resistance.

### BACKGROUND OF THE INVENTION

The present invention generally relates to the manufacture of semiconductor devices and more particularly to an improved dual damascene process for creating dual damascene structures.

Metal interconnections in very large scale integrated (VLSI) or ultra-large scale integrated (ULSI) circuits typically consist of interconnect structures containing patterned layers of metal wiring. Typical integrated circuit (IC) devices contain from three to fifteen layers of metal wiring. As feature sizes decrease and device density increases, the number of interconnect layers is expected to increase.

Creation of the structure for metal lines for back end of line (BEOL) semiconductor manufacturing requires creating vias between two metal line levels. Usually, this entails two discrete lithographic and RIE operations to create the vias and trenches. In this invention we propose a process sequence which will enable integrated via and line lithography followed by integrated via and line etch. A novel two-layered, negative tone resist based lithography is used to generate a dual damascene structure in the photoresist which is subsequently transferred into the underlying interlayer dielectric (ILD) using an appropriate etch process.

Creation of the structure for metal lines for BEOL semiconductor manufacturing requires creating metal line levels and via levels in a sequence such that the metal line levels are interconnected by via levels. Usually this entails two discrete lithographic and RIE operations to create the via and trench levels in separate steps.

A typical dual damascene process sequence has several disadvantages. First a planarizing layer is required for the second patterning level. This planarization is not completely uniform and typically results in some topography which nay cause problems for the second lithography step. Second, it is a high cost process because it requires a special planarizing layer and requires multiple steps, two passes through the lithography tool and two passes through the RIE tool. This results in a longer process time and increased cost. Third, in applications using a low (<4.0) dielectric constant material in the BEOL, RIE damage to the dielectric material may result from the required strip of the planarizing layer. This is especially severe for porous ultra low dielectric constant materials.

Other solutions have been proposed by others to solve these problems. U.S. Pat. No. 5,877,076 proposes using a combination of positive and negative resist in two separate patterning steps. However in this approach, additional time is required for the first photoresist layer. This development step could potentially create planarization issues. Additionally, this approach places the negative resist on top of the positive resist. Here, exposure of the negative resist in certain areas could cause the positive resist to dissolve and create adhesion problems and resist profile issues during etch in heavily patterned areas. Similarly, in U.S. Pat. No. 6,242,344, where a negative resist is placed on top of a positive resist before any patterning, the underlying positive photoresist will be exposed to some radiation and exhibit some level of film loss. This film loss could result in adhesion failure at the interface between resist layers.

Therefore, a need exists for an improved dual damascene process. Accordingly, it is an object of the present invention to provide an integrated lithography step which does both via and line level patterning with two layers of negative resist in separate exposure steps.

Another object of the present invention is to follow the lithography with an integrated RIE. These and other objects of the invention will become more apparent after referring to the following description of the invention.

### BRIEF SUMMARY OF THE INVENTION

The present invention provides a process sequence which will enable integrated via and line lithography followed by integrated via and line etch. A novel two-layered, negative resist based lithography is used to generate a dual damascene structure in the photoresist which is subsequently transferred into the underlying ILD using an appropriate etch process.

In a first embodiment of the present invention there is provided a method of dual damascene patterning through the use of a two-layered negative resist comprising the steps of providing a semiconductor substrate having an interlayer dielectric layer deposited thereon; forming a first negative resist layer on the interlayer dielectric layer; hole patterning the first negative resist layer by exposing and developing the first negative resist layer using a via level level mask; forming a second negative resist layer on the first negative resist layer; and line patterning the second negative resist layer by exposing and developing the second negative resist layer using a line level mask, thereby forming a via and line structure in the undeveloped resist.

In another embodiment of the present invention there is provided a method of dual damascene patterning through the use of a two-layered negative resist comprising the steps of providing a semiconductor substrate having an interlayer dielectric layer deposited thereon; forming a first negative resist layer on the interlayer dielectric layer; exposing the first negative resist layer using a via level level mask; forming a second negative resist layer on the first negative resist layer; and hole and line patterning the first and second negative resist layers by exposing and developing the first and second negative resist layers using a line level mask, thereby forming a via and line structure in the undeveloped resist. The methods may further comprise a bake after exposing the first and second negative resists.

In a preferred method of dual damascene patterning there is provided a two-layered negative resist and integrated RIE process comprising the steps of providing a semiconductor substrate having a cap layer thereon and an interlayer dielectric layer deposited on said cap layer; providing an etch stop layer on the interlayer dielectric layer and an organic layer on the etch stop layer; providing a hardmask layer on the organic layer; forming a first negative resist layer on the hardmask layer; hole patterning the first negative resist layer by exposing and developing the first negative resist layer using a via level level mask; forming a second negative resist layer on the first negative resist layer; and line patterning the second negative resist layer by exposing and developing the second negative resist layer using a line level mask, thereby forming a via and line structure in the undeveloped resist; and performing an oxide RIE to remove portions of the hardmask layer and transfer the via pattern into the surface of the organic layer.

The preferred method further comprises the steps of etching the vias in the organic layer to the interlayer dielectric layer; forming the vias in the ILD layer to a depth such that they are at least below the final line depth but less than approximately 80% of said ILD layer thickness; removing the resist over the line using a strip process thereby etching away the hardmask over the line structure; etching the line pattern through the organic layer into the ILD layer; etching the ILD layer using an etch chemistry that is sufficiently selective to the organic layer; etching the vias down to the cap layer; removing the remaining organic layer; and opening the cap layer with a RIE process thereby connecting the vias to electrical structures in the substrate.

The present invention also provides a method to correct via to line misalignment according to the disclosed method wherein the first negative resist layer is less sensitive than the second negative resist layer comprising the steps of providing the first negative resist with a thickness sufficient to be used for the entire etch process; providing the second negative resist with a thickness such that during the etch process the second negative resist fully consumed; and using a resist-only RIE process resulting in the transfer of the line structure into the first negative resist.

The present invention also provides a dual damascene structure comprising a semiconductor substrate having an interlayer dielectric layer deposited thereon; a first negative resist layer on the interlayer dielectric layer, the first negative resist layer having developed first negative resist features therein; a second negative resist layer on the first negative resist layer, the second negative resist layer having developed second negative resist features therein; and the second developed negative resist features having an area greater than or equal to the area of the first developed negative resist features.

The dual damascene structure may further comprise additional negative resist layers having developed negative resist features wherein each subsequent additional negative resist layer has developed negative resist features having an area greater or equal to the underlying developed negative resist features.

### BRIEF DESCRIPTION OF THE DRAWINGS

The features of the invention believed to be novel and the elements characteristic of the invention are set forth with particularity in the appended claims. The figures are for illustration purposes only and are not drawn to scale. The invention itself, however, both as to organization and method of operation, may best be understood by reference to the detailed description which follows taken in conjunction with the accompanying drawings in which:

FIGS. 1-5 are schematic views of the two-layered, negative resist based lithography process used to generate a dual damascene structure.

FIGS. 6-12 are schematic views of the integrated RIE process used to generate a two-layered, negative resist dual damascene structure.

FIGS. 12-16 are schematic views of methods to correct misalignment in the integrated two-layered, negative resist dual damascene structure.

### DETAILED DESCRIPTION OF THE INVENTION

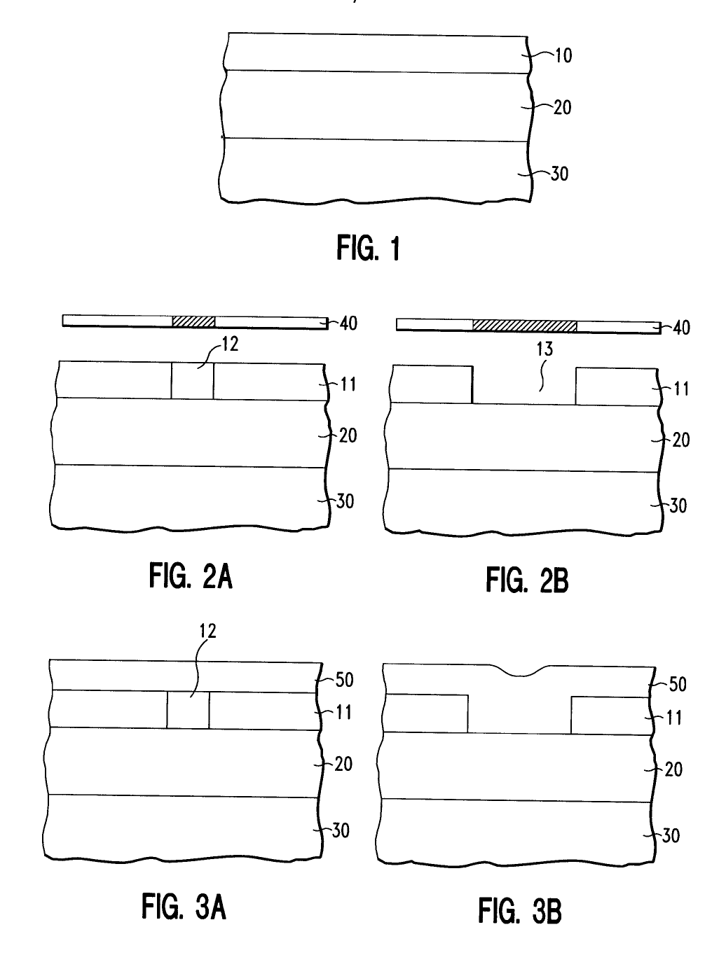

The lithography process sequence used to generate a dual damascene structure in the resist is described with reference to the accompanying drawings. FIG. 1 shows a schematic cross section view of an interlayer dielectric (ILD) layer 20 on a substrate 30. A first layer of a negative resist 10 is applied to the ILD layer 20 in a conventional manner such as spinning.

Referring now to FIGS. 2a, 2b the first negative resist layer 10 is exposed to light with a via level mask 40 resulting in a cross-linked exposed resist region 11 and an unexposed resist region 12. As is known in the art when a negative N-type photoresist is exposed to light cross-linking occurs. Mask 40 is used to expose only selected portions of the resist layer to light depending on the desired pattern to be developed. The unexposed areas will not be crosslinked and will be dissolved away to form the desired features. When the negative photoresist is developed, for example in a TMAH solution, only the unexposed areas of the negative resist are removed. The exposed resist is crosslinked and is not dissolved by the developing solution. The crosslinking process is aided by baking the resist after exposure.

In a first embodiment shown in FIG. 2a the resist layer 10 is baked but the unexposed resist 12 is not developed out. In a second embodiment shown in FIG. 2b the resist is baked and the unexposed resist 12 is developed and dissolved away to create the desired via features 13.

Referring to FIGS. 3a, 3b, a second layer of negative resist 50 is deposited on the first layer of negative resist. In the first embodiment shown in FIG. 3a, good planarity is achieved since none of the resist material has been removed and the second layer of negative resist 50 is deposited on exposed first resist 11 and unexposed first resist 12. In the second embodiment shown in FIG. 3b the second layer of negative resist is deposited on exposed first resist 11 and in the via feature 13. In the second embodiment shown in FIG. 3b the planarity may not be as good due to the absence of resist material in the unexposed areas. Embodiment 2 however avoids the issue of the intermixing of two resist layers because the uncrosslinked first layer of resist is developed away.

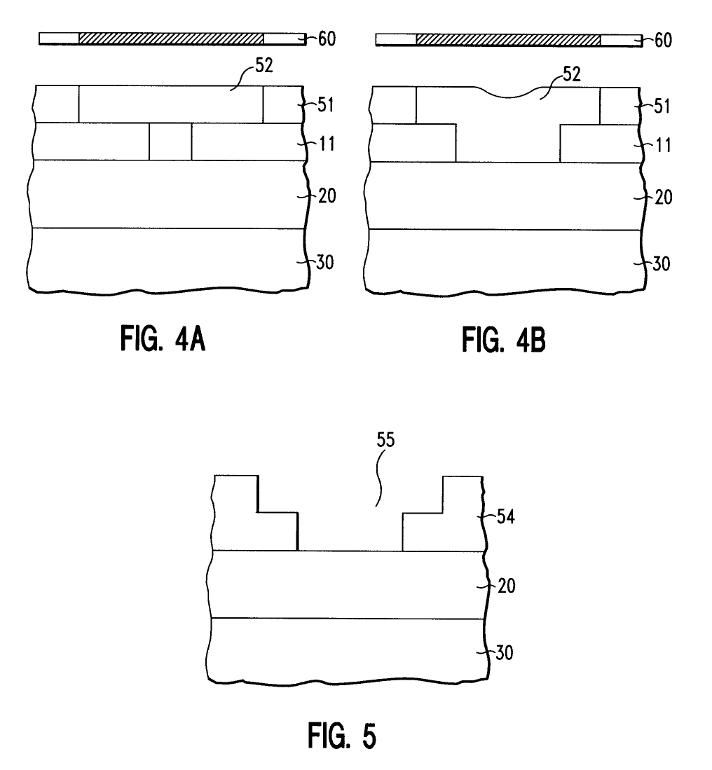

Referring to FIGS. 4a,4b, the second resist layer 50 is exposed with light through a line level mask 60 resulting in a cross-linked exposed resist region 51 and an unexposed resist region 52 which is not crosslinked. Additional light penetrating into bottom resist layer portion 11 has no effect since it is already crosslinked.

Referring to FIG. 5 the second resist 50 is developed and the unexposed resist 12, 52 is removed. At this stage both embodiments result in similar structures as the non-planarity in the second embodiment is developed away. FIG. 5 shows the resulting via and trench pattern 55 formed in the remaining resist material 54.

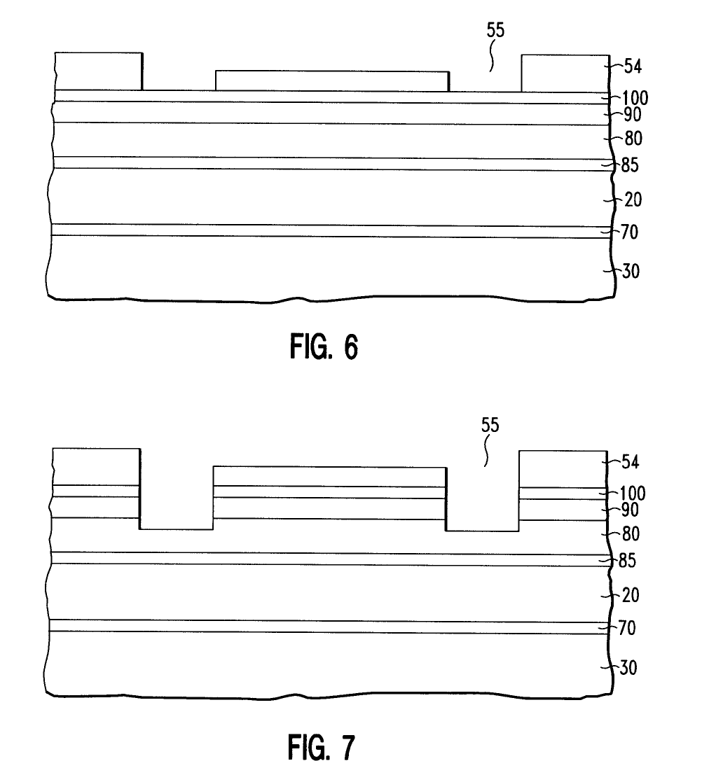

Referring now to FIG. 6 the integrated RIE process is described. FIG. 6 is a schematic cross section showing the dual damascene structure described above in more detail. The interconnect structure comprises a lower substrate 30 which is the lower portion of the semiconductor device and may contain logic circuit elements such as transistors. A cap layer 70 is typically deposited on the substrate 30 and then a dielectric layer 20. The cap layer 70 is typically comprised of silicon nitride, silicon carbide or silicon dioxide and acts as a diffusion barrier to prevent diffusion of conductive material into the dielectric and to protect any conductive material in the substrate against oxidation during further processing.

An etch stop layer 85, typically a TEOS oxide, may be deposited on the ILD layer 20. Next an organic planarizing layer 80 that also acts as a transfer masking layer is deposited. A hardmask layer 90 is deposited on the organic layer 80. The hardmask layer 90 is typically composed of silicon nitride, but may also be comprised of silicon oxide or silicon carbide. The hardmask layer 90 protects the organic layer 80 during RIE processing. An anti reflective coating layer (ARC) 100 is deposited on the hardmask layer 90. And then the resist 54 and via and trench pattern 55 are formed in the resist from the two-step negative resist lithography previously described.

Referring now to FIG. 7, once the resist is developed the process of forming the vias and trenches in a single RIE process can proceed. The first step in the fully integrated via and trench formation is to transfer the via and trench pattern 55 through the hard mask 90 and into the organic layer 80. A conventional ARC open and oxide RIE process is carried out creating the structure shown in FIG. 7 which illustrates the profile of the resist, vias, and trench after ARC open and oxide etch step. The ARC open and oxide RIE steps may be, but need not be, discrete steps.

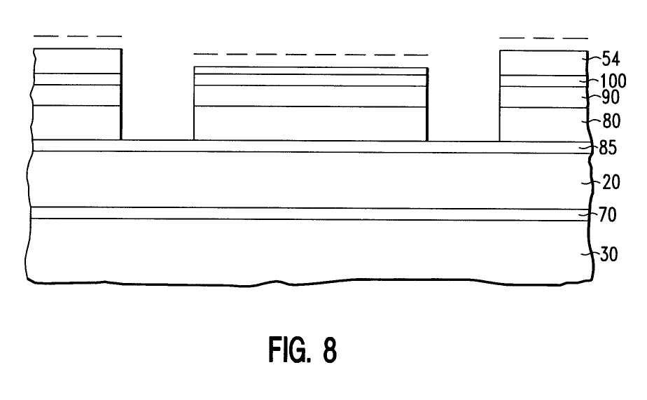

Referring now to FIG. 8, after the ARC open/oxide RIE steps are executed, the organic layer 80 is further etched forming the vias in this layer. During this organic layer etch some of the resist 54 is consumed. The vias are etched to the ILD layer 20 as shown in FIG. 8 which illustrates the transfer layer formation of vias in organic patterning layer 80.

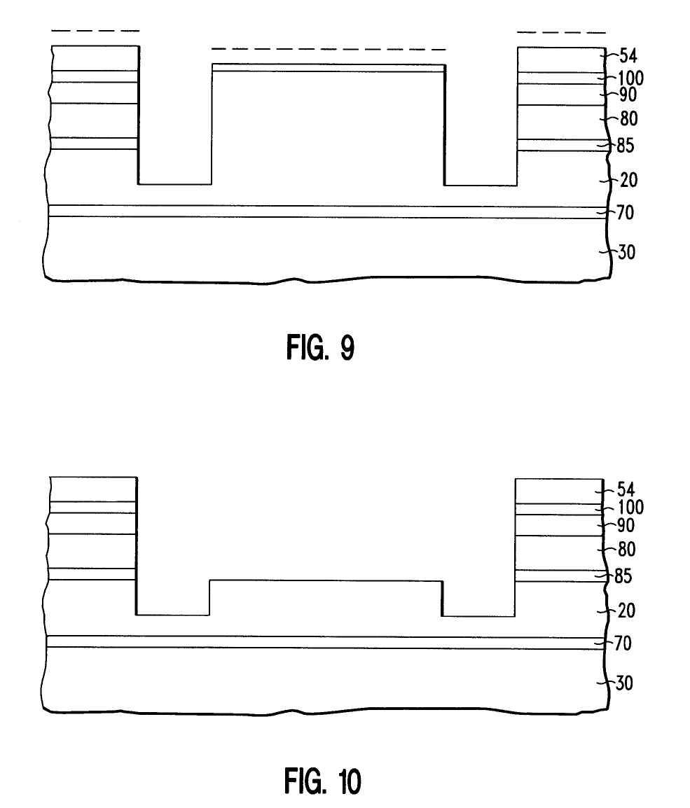

Referring now to FIG. 9, formation of the vias continues by etching the vias into the ILD layer 20. The depth of the vias into the ILD layer 20 is such that they are at least below the desired final trench depth but less than about 80% of the ILD layer thickness. During this step some additional amount of resist 54 over both the trench region and all other areas of the wafer is etched as indicated by the dashed lines. The conditions for etching a low K SiCOH ILD are such that selectivity to the resist prevents the clearing or partial clearing of the resist over the trench area. This is shown in FIG. 9 which illustrates partial via RIE into the ILD low k film 20. Some resist 54 remains over the trench region.

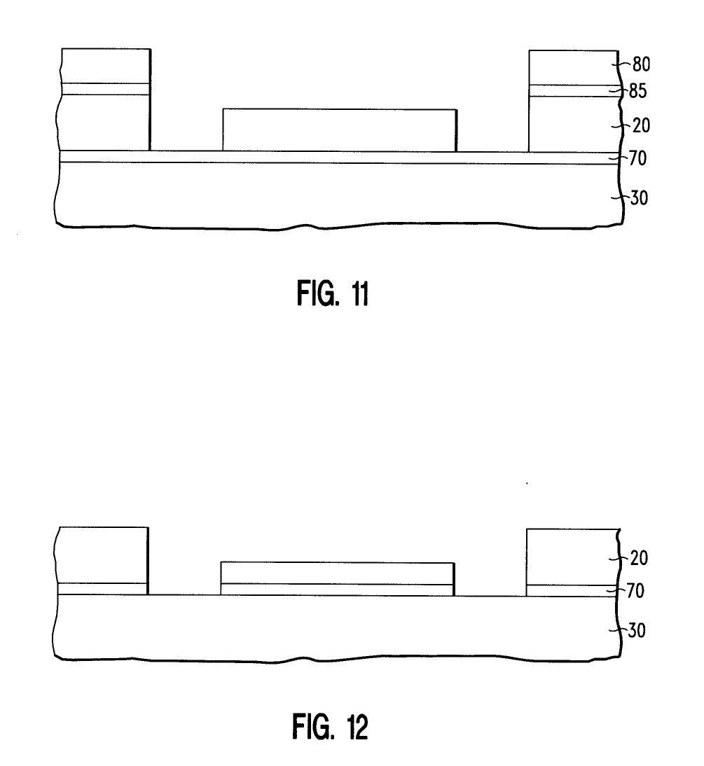

Referring now to FIG. 10, after the vias are formed, the resist over the trench is removed with a slight strip process and the ARC layer 100 and oxide hardmask 90 are etched away over the trench region. The resist over the remaining portion of the wafer remains intact. This step can be combined through proper choice of etch conditions with the hardmask RIE step. After removing the ARC layer 100 and hardmask 90 over the trench the trench pattern is etched through the organic layer 80 into the ILD layer 20. During this etch step the resist over the entire wafer is removed and the hardmask 90 under it protects the organic layer 80 underneath it. The structure is shown in FIG. 11 which illustrates the structure of the ILD layer 20 and organic patterning layer 80 after trench pattern formation in the transfer organic layer.

Referring now to FIG. 11, the ILD layer 20 is etched, with an etch chemistry that is sufficiently selective to the organic patterning layer 80. During the trench RIE step the remaining ARC layer 100 and hardmask layer 90 are removed and the vias are etched down to the cap layer 70 as shown in FIG. 11 which illustrates the transfer etch of the trench region into the ILD layer 20. Some of the organic patterning layer 80 can remain. Referring now to FIG. 12 the remaining organic patterning layer 80 and etch stop layer 85 is removed followed by a RIE step to open the cap layer 70 connecting the vias to electrical structures in the substrate 30 below as shown in FIG. 12 which illustrates the finished dual damascene RIE process. The cap layer 70 is etched and the organic patterning layer 80 is removed.

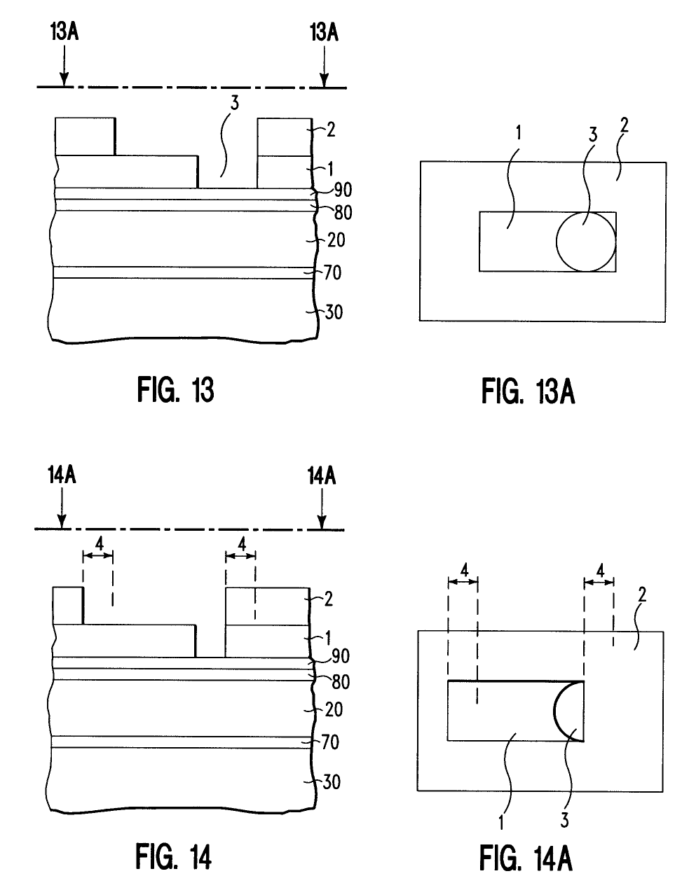

For any dual damascene process it is desirable that the via interconnect contact is not decreased due to misalignment between the via and trench photolithography steps. Such misalignment would reduce the size of the via opening and thereby adversely impact the via resistance. In situations where there is via/trench misalignment, an increase of the trench area is preferable to a reduction of the via contact area. Referring to FIG. 13 there is shown an ideal case for the integrated lithography process of the present invention. The left view is a schematic cross-sectional view and the right view is the corresponding top view. As shown there is no misalignment between via opening 3 and trench lithography as comprised of first negative resist 1 and second negative resist 2.

Referring now to FIG. 14 there is shown a situation where the integrated lithography process results in the trench lithography misaligned towards the left by a small distance 4. This situation is possible if the first negative resist 1 is equally or more sensitive to light than the second negative resist 2. Sensitive is understood to mean that the amount of light exposure required to cross-link the first negative resist 1 is less than or equal to the amount of light required to cross-link the second negative resist 2. In this situation, during the trench exposure of the second negative resist 2, the portion of first resist 1 in the misaligned overlap region of the via is also exposed and hence cross-linked. Misalignment results in the decrease in via opening due to exposure of the via resist. The overlap region 4 corresponds to the decreased via area as shown in the top down schematic of FIG. 14. In this situation RIE processes cannot be developed to regain the original via contact area since this information has been permanently lost after the integrated lithography since the cross-linked region will not be dissolved away.

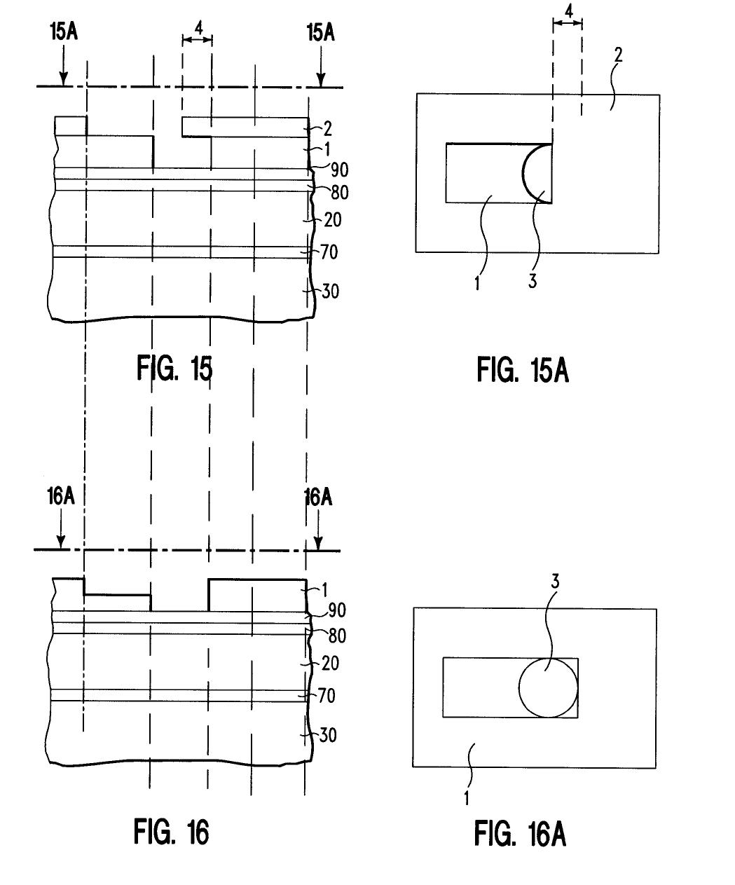

Another possible via/trench misalignment situation is when the first negative resist 1 is less sensitive than the second negative resist 2. This could occur where the second resist is applied over the first resist without first developing the first resist. The amount of light used to expose the second negative resist 2 should be less than that required to cross-link the first negative resist 1. Exposure with an appropriate amount of light causes the exposed second negative resist 2 to crosslink while the first negative resist 1, even if exposed, will not crosslink. In this case the via contact area is retained in the resist stack after the integrated lithography since the uncrosslinked first negative resist 1 can still be etched away and a process sequence that is outlined below may be used to avoid the decrease of the via contact area for misaligned structures such as shown in FIG. 15.

This embodiment of the present invention where the resist stack and the initial etch process that may be used to retain the via contact area in cases of misalignment is described in more detail with reference to FIGS. 15 and 16. The structure after the integrated lithography as described in the above paragraph is shown in FIG. 15. The second negative resist 2 is not used during the ILD etch. The second negative resist 2 will be a sacrificial etch resist and will not be used during the etch of the ILD stack. The first negative resist 1 is thick enough such that it can be used for the entire integrated etch process as described above. The starting integrated resist stack shown in FIG. 15 is then subject to a resist-only RIE process resulting in the transfer of the trench structure of the first negative resist 1 into the second negative resist 2. The etch process that is used may be an organic etch process that selectively etches the resist without etching the underlying RIE hard mask layer. The material and thickness of the second negative resist 2 and the etch chemistry are chosen so that the appropriate trench depth is obtained in the first negative resist 1 after the trench transfer etch. As is shown in FIG. 16, the transfer of the trench pattern in the second negative resist 2 is taken to its fullest amount where the second negative resist 2 is fully consumed.

The second negative resist 2 pattern is transferred into the first negative resist 1 and is consumed during the transfer process. When the second negative resist 2 is completely transferred and consumed and the first negative resist layer 1 is fully exposed, the process needs to be stopped. If the composition of the second negative resist 2 is different than the first negative resist 1 the emission intensity of the etching plasma will change indicating the clearing of the second negative resist 2. If the compositions of both the first and second resists are the same a surface treatment to first resist 1 can be used to densify or change the top surface structure slightly. This change will also result in a change in the etch rate of the resist stack and the interface of first resist 1 to second resist 2 will be noticed in the etching plasma emission. If a change of the top surface is not practical, a thin intermediary layer can be added between first resist 1 and second resist 2. The intermediary layer can be a typical ARC film or an organic polymer or inorganic dielectric film commonly found in the semiconductor industry. The intermediary film is typically thin enough to not adversely affect the lithographic processes used, but thick enough to effect an emission change in the etching plasma as the second resist 2 is cleared.

Normal plasma etching of typical resists is readily carried out with plasmas using gas compositions of Ar/O₂, Ar/H₂, Ar/NH₃, or N₂/H₂ for example. In all cases the reaction is anisotropic proceeding in a top down manner. When the composition or structure changes the plasma etch rate also changes. In cases where the composition changes from an organic polymer to a metal oxide, nitride, or carbide, the etch rate drops dramatically, often to zero. These changes in film properties result in a measurable emission change in the plasma. There is some lateral sputter driven etch that can be used to help alleviate small amounts of misalignment. After this etch the ILD etch can be done as described earlier.

The methods described above can be used with more than two layers of negative resist. Any desired number of negative resist layers can be used to provide a variety of dual damascene structures having multiple layers with developed features therein wherein each subsequent additional negative resist layer has developed negative resist features having an area greater or equal to the underlying developed negative resist features.

It will be apparent to those skilled in the art having regard to this disclosure that other modifications of this invention beyond those embodiments specifically described here may be made without departing from the spirit of the invention. Accordingly, such modifications are considered within the scope of the invention as limited solely by the appended claims.

What is claimed is:

1. A method of dual damascene patterning through the use of a two-layered negative resist comprising the steps of:
providing a semiconductor substrate having an interlayer dielectric layer deposited thereon;
forming a first negative resist layer on said interlayer dielectric layer;
hole patterning said first negative resist layer by exposing and developing said first negative resist layer using a via level level mask;
forming a second negative resist layer on said first negative resist layer; and
line patterning said second negative resist layer by exposing and developing said second negative resist layer using a line level mask, thereby forming a via and line structure in the undeveloped resist.

2. The method of claim 1 further comprising a bake after exposing said first and second negative resist layers.

3. The method of claim 1 wherein said first negative resist layer is equally or more sensitive than said second negative resist layer.

4. The method of claim 1 wherein said first negative resist layer is less sensitive than said second negative resist layer.

5. A method of dual damascene patterning through the use of a two-layered negative resist comprising the steps of:
providing a semiconductor substrate having an interlayer dielectric layer deposited thereon;
forming a first negative resist layer on said interlayer dielectric layer;
exposing said first negative resist layer using a via level level mask;
forming a second negative resist layer on said first negative resist layer; and
hole and line patterning said first and second negative resist layers by exposing and developing said first and second negative resist layers using a line level mask, thereby forming a via and line structure in the undeveloped resist.

6. The method of claim 5 further comprising a bake after exposing said first and second negative resists.

7. The method of claim 5 wherein said first negative resist layer is equally or more sensitive than said second negative resist layer.

8. The method of claim 5 wherein said first negative resist layer is less sensitive than said second negative resist layer.

9. A method of dual damascene patterning through the use of a two-layered negative resist and integrated RIE process comprising the steps of:
providing a semiconductor substrate having a cap layer thereon and an interlayer dielectric layer deposited on said cap layer;
providing an etch stop layer on said interlayer dielectric layer and an organic layer on said etch stop layer;
providing a hardmask layer on said organic layer;
forming a first negative resist layer on said hardmask layer;
hole patterning said first negative resist layer by exposing and developing said first negative resist layer using a via level level mask;
forming a second negative resist layer on said first negative resist layer; and
line patterning said second negative resist layer by exposing and developing said second negative resist layer using a line level mask, thereby forming a via and line structure in the undeveloped resist; and
performing an oxide RIE to remove portions of said hardmask layer and transfer said via pattern into the surface of said organic layer.

10. The method of claim 9 further comprising the step of etching the vias in said organic layer to said interlayer dielectric layer.

11. The method of claim 10 further comprising the steps of forming the vias in said ILD layer to a depth such that they are at least below the final line depth but less than approximately 80% of said ILD layer thickness.

12. The method of claim 11 further comprising the steps of:
removing the resist over the line using a strip process thereby etching away said hardmask over said line structure; and
etching said line pattern through said organic layer into said ILD layer.

13. The method of claim 12 further comprising the steps of:
etching said ILD layer using an etch chemistry that is sufficiently selective to said organic layer;
etching the vias down to said cap layer;
removing the remaining said organic layer; and
opening said cap layer with a RIE process thereby connecting the vias to electrical structures in said substrate.

14. The method of claim 9 further comprising the step of providing an ARC layer on said hardmask layer.

15. The method of claim 9 wherein said cap layer is comprised of a material selected from the group consisting of silicon nitride, silicon carbide and silicon dioxide.

16. The method of claim 9 wherein said etch stop layer is an oxide.

17. The method of claim 9 wherein said hardmask layer is comprised of a material selected from the group consisting of silicon nitride, silicon oxide and silicon carbide.

18. The method of claim 9 further comprising a bake after exposing said first and second negative resists.

19. A method to correct via to line misalignment according to the method of claim 9 wherein said first negative resist layer is less sensitive than said second negative resist layer comprising the steps of:
providing said first negative resist with a thickness sufficient to be used for the entire etch process;
providing said second negative resist with a thickness such that during the etch process said second negative resist fully consumed; and
using a resist-only RIE process resulting in the transfer of said line structure into said first negative resist.

20. A dual damascene structure comprising:
a semiconductor substrate having an interlayer dielectric layer deposited thereon;
a first negative resist layer on said interlayer dielectric layer, said first negative resist layer having developed first negative resist features therein;
a second negative resist layer on said first negative resist layer, said second negative resist layer having developed second negative resist features therein; and
said second developed negative resist features having an area greater than or equal to the area of said first developed negative resist features.

21. The dual damascene structure of claim 20 further comprising additional negative resist layers having developed negative resist features wherein each subsequent additional negative resist layer has developed negative resist features having an area greater or equal to the underlying developed negative resist features.
